(19) United States
(12) Patent Application Publication
(10) Pub. No.: US 2021/0042943 A1
(43) Pub. Date: Feb. 11, 2021

(54) SCANNING ELECTRON MICROSCOPE

(71) Applicant: Shimadzu Corporation, Kyoto (JP)

(72) Inventors: Ryuta MATSUMOTO, Kyoto (JP); Kiyoshi OGAWA, Kyoto (JP); Tomomi TAMURA, Kyoto (JP); Hiroki MAEDA, Kyoto (JP)

(21) Appl. No.: 16/985,700

(22) Filed: Aug. 5, 2020

(30) Foreign Application Priority Data
Aug. 7, 2019 (JP) 2019-145047

(51) Int. Cl. G06T 7/40; G06T 11/60; H01J 37/22; H01J 37/29; H01J 37/285

(52) U.S. Cl. CPC G06T 7/40; G06T 11/60; H01J 37/222; H01J 37/292; H01J 37/285; H01J 2237/2806; G06T 2207/20036; G06T 2207/10061; H01J 2237/285; H01J 2237/2807; H01J 2237/2804; G06T 2200/24

(57) ABSTRACT

A scanning electron microscope is provided that is capable of displaying an image highly visible for a user when an image is displayed by visualization by combining morphological image information with component image information. A scanning electron microscope 1 for observing a sample S by irradiating the sample S with an electron ray, the scanning electron microscope 1 includes: a morphological calculation unit 24 configured to calculate intensity data of at least one of secondary electrons and reflected electrons obtained from the sample S to obtain morphological image information of the sample S; a component calculation unit 34 configured to calculate spectrum data of X-ray energy obtained from the sample S to obtain component image information of the sample S; and a display unit 50 configured to display an image visualized by combining the morphological image information with the component image information, wherein the morphological calculation unit 24 is configured to change the morphological image information in accordance with one or more morphological image parameters input by a user, and the component calculation unit 34 is configured to change the component image information in accordance with one or more component image parameters input by a user.

### BACKGROUND OF THE INVENTION

### 1. Field of the Invention

The present invention relates to a scanning electron microscope (SEM) to measure a surface profile, composition distribution, and the like of a sample.

### 2. Description of the Related Art

Scanning electron microscopes have been used as a device to measure a surface profile, composition distribution, and the like of a sample. Such a scanning electron microscope focuses electron rays from an electron gun to irradiate a sample surface as an electron beam and detect secondary electrons, reflected electrons, X-rays, light, and the like generated from the sample and is capable of measuring a three dimensional shape of the sample surface by scanning an irradiation position with the electron beam on the sample surface, composition distribution on the sample surface, and the like (e.g., JP 2010-060389A).

Scanning electron microscopes are thus capable of obtaining a secondary electron image indicating the three dimensional shape of the sample surface and the composition distribution (so-called component image) on the sample surface while the composition distribution information does not contain information on the shape. To allow intuitive observation by a user, there is a proposed configuration to display the secondary electron image and the composition distribution by superposition (e.g., Japanese Patent No. 5286598).

### SUMMARY

The scanning electron microscope described in Japanese Patent No. 5286598, in which the secondary electron image (i.e., morphological image) and the composition distribution (i.e., component image) are displayed by superposition, allows intuitive observation compared with a configuration to separately observe the secondary electron image and the composition distribution.

However, a case of simply displaying the secondary electron image and the composition distribution by superposition as the configuration of Japanese Patent No. 5286598 has a problem that the image does not have to be highly visible for a user due to differences in image parameters (e.g., brightness, contrast, etc.) between them.

The present invention has been made in view of the above circumstances and it is an object thereof to provide a scanning electron microscope capable of displaying an image highly visible for a user for displaying a morphological image and a component image by superposition (i.e., for displaying an image visualized by combining morphological image information with component image information).

A first aspect of the present invention relates to a scanning electron microscope for observing a sample by irradiating the sample with an electron ray, the scanning electron microscope including:

a morphological calculation unit configured to calculate intensity data of at least one of secondary electrons and reflected electrons obtained from the sample to obtain morphological image information of the sample;

a component calculation unit configured to calculate spectrum data of X-ray energy obtained from the sample to obtain component image information of the sample; and

a display unit configured to display an image visualized by combining the morphological image information with the component image information, wherein

the morphological calculation unit is configured to change the morphological image information in accordance with one or more morphological image parameters input by a user, and

the component calculation unit is configured to change the component image information in accordance with one or more component image parameters input by a user.

A second aspect of the present invention relates to a scanning electron microscope for observing a sample by irradiating the sample with an electron ray, the scanning electron microscope including:

a morphological calculation unit configured to calculate intensity data of at least one of secondary electrons and reflected electrons obtained from the sample to obtain morphological image information of the sample;

a component calculation unit configured to calculate spectrum data of X-ray energy obtained from the sample to obtain component image information of the sample; and

a display unit configured to display an image visualized by combining the morphological image information with the component image information, wherein

the display unit configured to display values of two arbitrary parameters related to a component of the sample as a point or region on a two dimensional map, and

the component calculation unit is configured to change the component image information in accordance with a position of the point or region on the two dimensional map specified by a user.

The present invention allows a user to separately change each image parameter for displaying an image visualized by combining the morphological image information with the component image information in the scanning electron microscope. This allows a user to obtain (display) a most visible image.

### BRIEF DESCRIPTION OF THE DRAWINGS

FIG. 1 is a schematic block diagram illustrating a configuration of a scanning electron microscope according to a first embodiment of the present invention.

FIG. 2 is a chart illustrating an example of a display screen of a display unit of the scanning electron microscope according to the first embodiment of the present invention.

FIG. 3 is a chart illustrating functions of a two dimensional map in FIG. 2.

FIG. 4 is a chart illustrating an example of a display screen of a display unit of a scanning electron microscope according to a second embodiment of the present invention.

FIG. 5 is a chart illustrating a modification of a two dimensional map in FIG. 4.

FIG. 6 is a chart illustrating an example of a display screen of a display unit of a scanning electron microscope according to a third embodiment of the present invention.

### DETAILED DESCRIPTION OF THE PREFERRED EMBODIMENTS

The scanning electron microscope of the present invention is described below in detail based on preferred embodiments illustrated in the attached drawings.

### First Embodiment

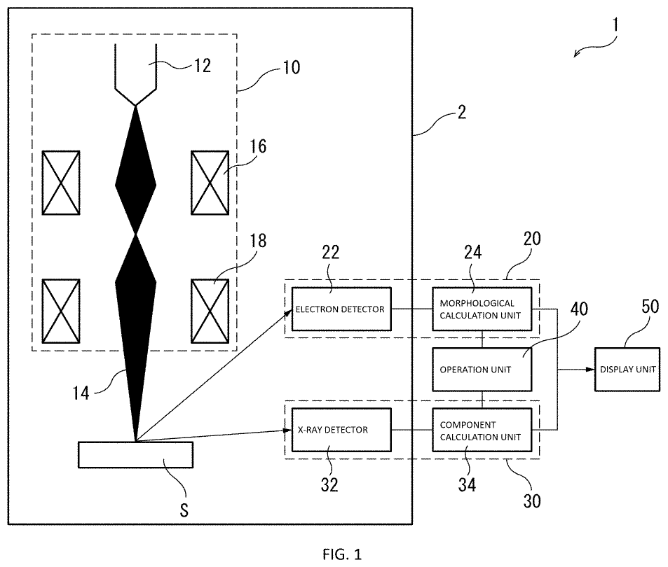

FIG. 1 is a schematic block diagram illustrating a configuration of a scanning electron microscope 1 according to the first embodiment of the present invention. As illustrated in FIG. 1, the scanning electron microscope 1 in the present embodiment includes an electron gun 10, a morphological image generation unit 20, a component image generation unit 30, an operation unit 40, a display unit 50, and a housing 2 to place the electron gun 10.

The electron gun 10 is provided with an electron source 12 to emit electron rays 14, a condenser lens 16 to focus the electron rays 14, and an objective lens 18 and irradiates a sample S with the electron rays 14. The electron gun 10 is also provided with a scanning coil, not shown, to scan the sample S with the electron rays 14 to allow free movement of an irradiation position with the electron rays 14 on a surface of the sample S by controlling energization of the scanning coil. The electron gun 10 is placed in the housing 2 connected to an evacuation mechanism, not shown, to keep the inside of the housing 2 at a degree of vacuum allowing the electron source 12 to generate electrons.

The morphological image generation unit 20 is a device to generate a morphological image (SEM image) of a surface of the sample S and is configured with an electron detector 22 to detect reflected electrons or secondary electrons generated by irradiation of the sample S with the electron rays and a morphological calculation unit 24 to receive data from the electron detector 22 for generation of the morphological image. When the sample S is scanned with the electron rays 14, the electron detector 22 sequentially outputs signals indicating the intensity of the detected electrons to the morphological calculation unit 24. The morphological calculation unit 24 obtains a brightness value of a pixel corresponding to each point on the sample S based on the intensity of the signals sequentially input from the electron detector 22 to generate image data of the morphological image (morphological image information).

The component image generation unit 30 is a device to generate a component image (composition distribution) of the sample S and is configured with an X-ray detector 32 to detect characteristic X-rays generated by irradiation of the sample S with the electron rays and a component calculation unit 34 to receive data from the X-ray detector 32 for generation of the component image. When the sample S is scanned with the electron rays 14, the X-ray detector 32 generates a pulse current with a current value in proportion to the energy of the detected characteristic X-rays to output to the component calculation unit 34. The component calculation unit 34 has a multichannel analyzer, not shown, to sort the pulse currents input from the X-ray detector 32 in accordance with the current values and count the pulse currents at each current value and obtains spectrum data of the characteristic X-rays by processing of the multichannel analyzer. The component calculation unit 34 performs multivariate analysis (e.g., principal component analysis, cluster analysis, etc.) of the spectrum data of the characteristic X-rays thus obtained for classification into each component to assign predetermined color information and thus generates image data of the component image (component image information).

Specifically, in a case of cluster analysis as the multivariate analysis, for example, pixel Nos. (numbers indicating the positions of the respective pixels) are aligned with the similarity of the spectrum at each analysis point and distances between the clusters are plotted on the ordinate to classify the clusters into a predetermined distance to assign predetermined color information to each cluster.

In a case of principal component analysis as the multivariate analysis, for example, arbitrary principal components 1 through 3 are given and the contribution ratios of the principal components are converted to RGB values to assign predetermined color information to each analysis point.

The components herein include elements, compounds, alloys, phases, and the like.

The operation unit 40 is a so-called user interface. The operation unit 40 is connected to the morphological calculation unit 24 and the component calculation unit 34 and changes image parameters (e.g., brightness, contrast) of the morphological image and image parameters (e.g., brightness, contrast) of the component image in accordance with user input. A change in the image parameters of the morphological image causes a change in the image data of the morphological image (morphological image information) and thus the morphological image to be displayed on the display unit 50 is changed. A change in the image parameters of the component image causes a change in the image data of the component image (component image information) and thus the component image to be displayed on the display unit 50 is changed.

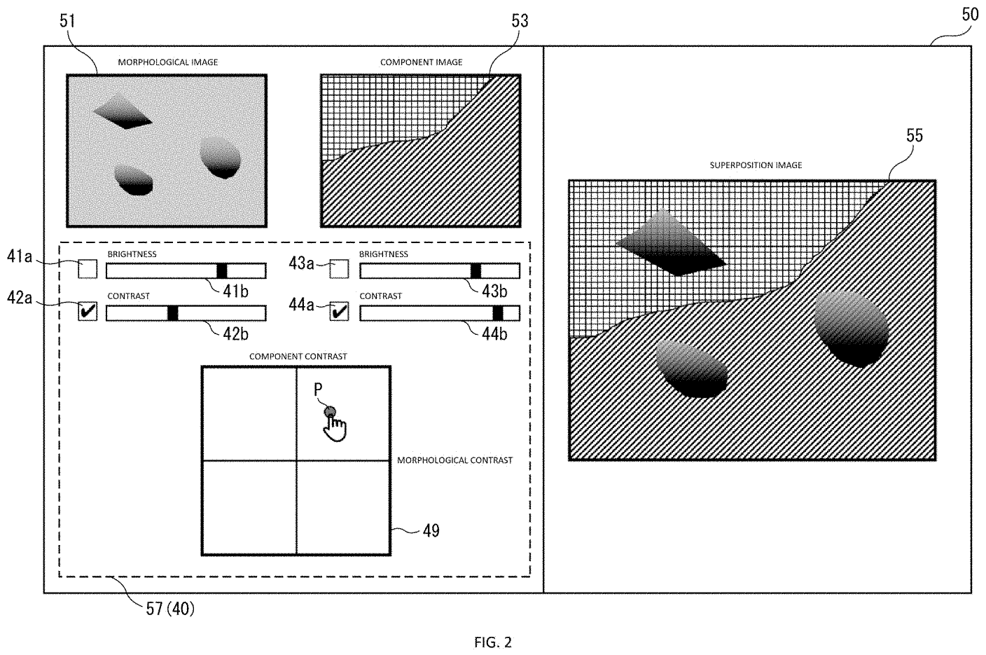

The display unit 50 is connected to the morphological image generation unit 20 and the component image generation unit 30 and is a display device to display the morphological image, the component image, and the like. FIG. 2 is a chart illustrating the display unit 50 of the scanning electron microscope 1 in the present embodiment and illustrates an example of a display screen of the display unit 50. As illustrated in FIG. 2, the display unit 50 in the present embodiment is configured with a so-called touch screen and has the operation unit 40 integrally formed in a portion (area surrounded by a broken line) of the display screen of the display unit 50.

The display screen of the display unit 50 has a morphological image display area 51, a component image display area 53, a superposition image display area 55, an image parameter display area 57 to display the image parameters of the morphological image and the image parameters of the component image, respectively formed therein.

The display unit 50 in the present embodiment is provided with a control unit (e.g., a CPU, etc.), not shown, and is configured to allow various types of calculation.

The morphological image display area 51 is an area to display the morphological image, where the control unit, not shown, of the display unit 50 generates the morphological image from the image data of the morphological image (morphological image information) input from the morphological calculation unit 24 to be displayed in the area 51.

The component image display area 53 is an area to display the component image, where the control unit, not shown, of the display unit 50 generates the component image from the image data of the component image (component image information) input from the component calculation unit 34 to be displayed in the area 53. It should be noted that, although FIG. 2 illustrates the two types of color information by two types of hatching, the actual component image is displayed as a color image in two colors.

The superposition image display area 55 is an area to display a superposition image produced by superposing the morphological image and the component image (i.e., image visualized by combining the morphological image information and the component image information), where the control unit, not shown, of the display unit 50 calculates the image data of the morphological image input from the morphological calculation unit 24 and the image data of the component image input from the component calculation unit 34 and generates the superposition image to be displayed in the area 55.

Specifically, the display unit 50 in the present embodiment obtains brightness Y at each analysis point (each pixel) based on the image data of the morphological image input from the morphological calculation unit 24 and assigns color information at each analysis point (each pixel) based on the image data of the component image input from the component calculation unit 34 to color difference signals U and V to superpose the morphological image and the component image in a YUV color space. The YUV color space is then converted to an RGB color space by formulae (1) through (3) below to generate the superposition image.

R=1.000Y+1.402V (1)

G=1.000Y−0.3444U−0.714V (2)

B=1.000Y+1.772U (3)

As just described, in the present embodiment, the image data of the morphological image is assigned to the brightness Y and the image data of the component image is assigned to the color difference signals U and V to be expressed in a YUV color space once, thereby superposing the morphological image and the component image.

Such a configuration allows superposition of the morphological image and the component image by simple arithmetic processing, whereas a problem of not allowing expression in an RGB color space (i.e., the RGB values not falling within the range from 0 to 255) sometimes arises upon the conversion by the formulae (1) through (3) to an RGB color space because the image data of the morphological image is simply assigned to the brightness Y.

To solve this problem, if the superposition image cannot be expressed in an RGB color space, the brightness Y is fixed and the U/V is also fixed to adjust the color difference signals U and V to fall within the RGB color space. If a superposition image cannot be expressed in an RGB color space, such a configuration allows all points to be expressed in an RGB color space by converting an original point to the closest point in the RGB color space.

The image parameter display area 57 is an area to display the image parameters of the morphological image and the image parameters of the component image. As illustrated in FIG. 2, the image parameter display area 57 is configured to display a check box 41a and a slider 41b to adjust the brightness of the morphological image, a check box 42a and a slider 42b to adjust the contrast of the morphological image, a check box 43a and a slider 43b to adjust the brightness of the component image, a check box 44a and a slider 44b to adjust the contrast of the component image, and a two dimensional map 49 to simultaneously adjust two types of image parameter.

The image parameter display area 57 in the present embodiment has the operation unit 40 integrally formed in the area 57 to allow a change in each image parameter, where each image parameter can be changed by a touching operation or a dragging operation of the check boxes 41a, 42a, 43a, and 44a, the sliders 41b, 42b, 43b, and 44b, and the two dimensional map 49 in the image parameter display area 57.

The slider 41b is a slider to adjust the brightness value of the morphological image and a user can change the brightness value of the morphological image by a touching operation of the slider 41b.

The slider 42b is a slider to adjust a contrast value of the morphological image and a user can change the contrast value of the morphological image by a touching operation of the slider 42b.

The slider 43b is a slider to adjust the brightness value of the component image and a user can change the brightness value of the component image by a touching operation of the slider 43b.

The slider 44b is a slider to adjust the contrast value of the component image and a user can change the contrast value of the component image by a touching operation of the slider 44b.

The check boxes 41a, 42a, 43a, and 44a are provided to select two image parameters to be adjusted on the two dimensional map 49. For example, as illustrated in FIG. 2, when a user touches and selects the check boxes 42a and 44a, the contrast of the morphological image and the contrast of the component image are selected as the image parameters allowed to be adjusted on the two dimensional map 49 and are set to allow simultaneous adjustment.

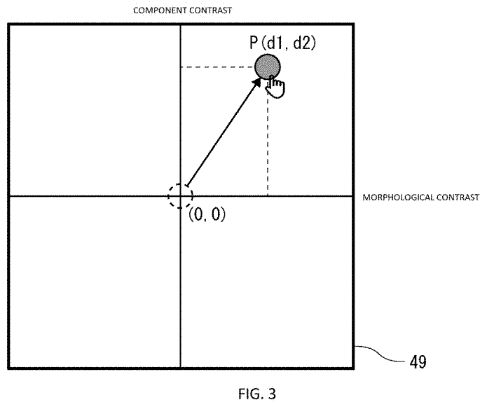

FIG. 3 is a chart illustrating functions of the two dimensional map 49. As illustrated in FIG. 3, when a user touches a point P on the two dimensional map 49, two dimensional coordinate values (d1, d2) of the point P are selected to set the contrast value of the component image corresponding to the coordinate value d1 and the contrast value of the morphological image corresponding to the coordinate value d2. Use of the two dimensional map 49 thus allows a simultaneous change in two types of image parameter by one operation.

As just described, operation of the check boxes 41a through 44a, the sliders 41b through 44b, and the two dimensional map 49 in the image parameter display area 57 allows changes in the image parameters (brightness and contrast) of the morphological image and the image parameters (brightness and contrast) of the component image. When the image parameters (brightness and contrast) of the morphological image and the image parameters (brightness and contrast) of the component image are changed, the contents of the change are input to the morphological calculation unit 24 and the component calculation unit 34 to be reflected on the morphological image displayed in the morphological image display area 51, the component image displayed in the component image display area 53, and the superposition image in the superposition image display area 55.

The configuration in the present embodiment accordingly allows a user to obtain a most visible image by changing the image parameters of the morphological image and the component image while looking at the morphological image, the component image, and the superposition image displayed in the display unit 50.

Although the present embodiment has been described as above, the present invention is not limited to the above configuration and may be variously modified within the scope of the technical spirit of the present invention.

For example, although the component image generation unit 30 in the present embodiment is described to generate a component image from the spectra of the characteristic X-rays, reflected electron energy or cathodoluminescence may be used instead of the spectra of the characteristic X-rays as long as it is capable of assigning color information by classification into each component.

### Second Embodiment

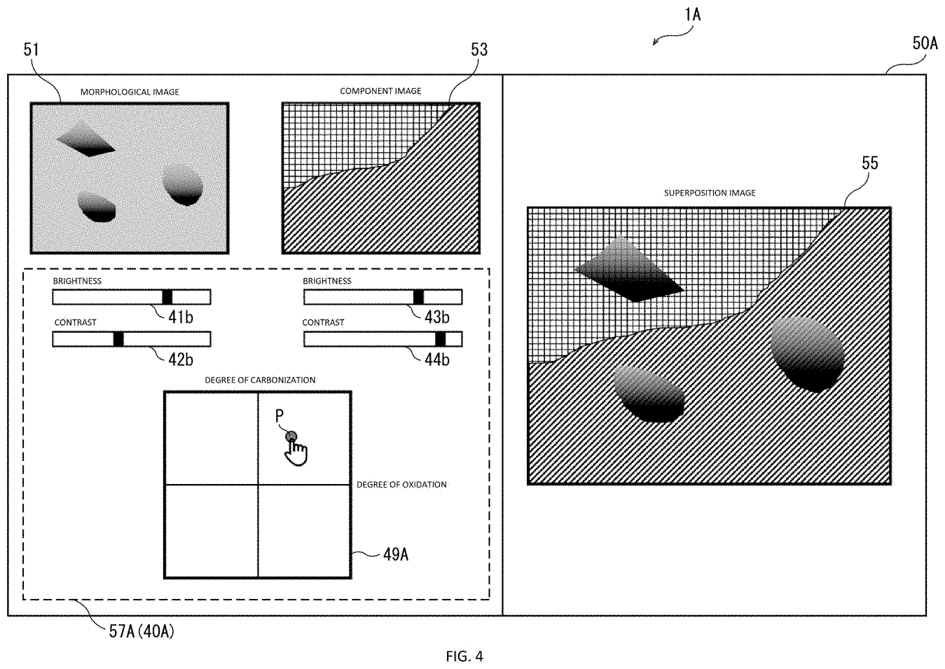

FIG. 4 is a chart illustrating a display unit 50A of a scanning electron microscope 1A according to the second embodiment of the present invention and illustrates an example of a display screen of the display unit 50A. The display unit 50A in the present embodiment is different from the display unit 50 of the first embodiment in that an image parameter display area 57A does not have the check boxes 41a, 42a, 43a, and 44a and has a two dimensional map 49A configured to allow adjustment of settings of a degree of oxidation and a degree of carbonization. It should be noted that the degree of oxidation herein means an amount of signal in components containing oxygen (e.g., peak intensity of ferrous oxide) and the degree of carbonization herein means an amount of signal in components containing carbon.

In the present embodiment, the component calculation unit 34 of the component image generation unit 30 performs multivariate analysis (e.g., principal component analysis, cluster analysis, etc.) of the spectra of the characteristic X-rays obtained by the X-ray detector 32 for classification into each component to assign predetermined color information and also generates image data of the component image (component image information) to have a brightness value in accordance with the degree of oxidation and the degree of carbonization of each element.

Settings of the degree of oxidation and the degree of carbonization are allowed to be displayed on the two dimensional map 49A and to be changed. When a user touches a point P on the two dimensional map 49A, the two dimensional coordinate values of the point P are selected to set a high brightness value for elements having not more than (or not less than) a degree of oxidation and a degree of carbonization corresponding to the coordinate values and to display the elements with emphasis.

That is, in the present embodiment, the image parameter (brightness) of the component image is configured to be changed by the degree of oxidation and the degree of carbonization set by a user and thus the degree of oxidation and the degree of carbonization are parameters related to the image parameter of the component image.

As just described, the present embodiment is configured to change the parameters related to the image parameter (i.e., the degree of oxidation and the degree of carbonization) using the two dimensional map 49A, thereby changing the brightness values of the component image and the superposition image to obtain an image highly visible for a user.

It should be noted that, although the display unit 50A in the present embodiment is described not to have the check boxes 41a, 42a, 43a, and 44a in the image parameter display area 57A, the image parameter display area 57A may be provided with check boxes corresponding to the respective image parameters similar to the first embodiment. In this case, a touching operation on a check box by a user causes selection of values of two parameters from a parameter group including one or more image parameters of the morphological image, one or more image parameters of the component image, and an arbitrary parameter related to any of the morphological or component image parameters (e.g., a degree of oxidation and a degree of carbonization) to be displayed on the two dimensional map.

### Modification of Second Embodiment

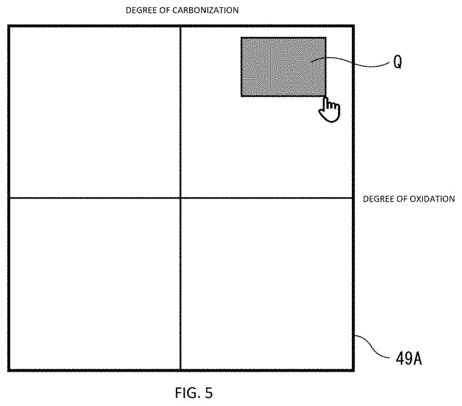

FIG. 5 is a chart illustrating a modification of the two dimensional map 49A illustrated in FIG. 4. Although the two dimensional map 49A in the second embodiment is described to select the two dimensional coordinate values of the point P touched by a user, as illustrated in FIG. 5, a user may touch and surround a predetermined region Q on the two dimensional map 49A to select the predetermined region Q.

In this case, a high brightness value is set for elements having a degree of oxidation and a degree of carbonization that are in ranges corresponding to the predetermined region Q to display the elements with emphasis.

It should be noted that, although the second embodiment and the above modification are configured to allow the settings of the degree of oxidation and the degree of carbonization to be changed as a sort of parameter related to the image parameter, they are not limited to such a configuration and the parameters allowed to be set by a user may be, for example, cluster hierarchies in cluster analysis and the like.

### Third Embodiment

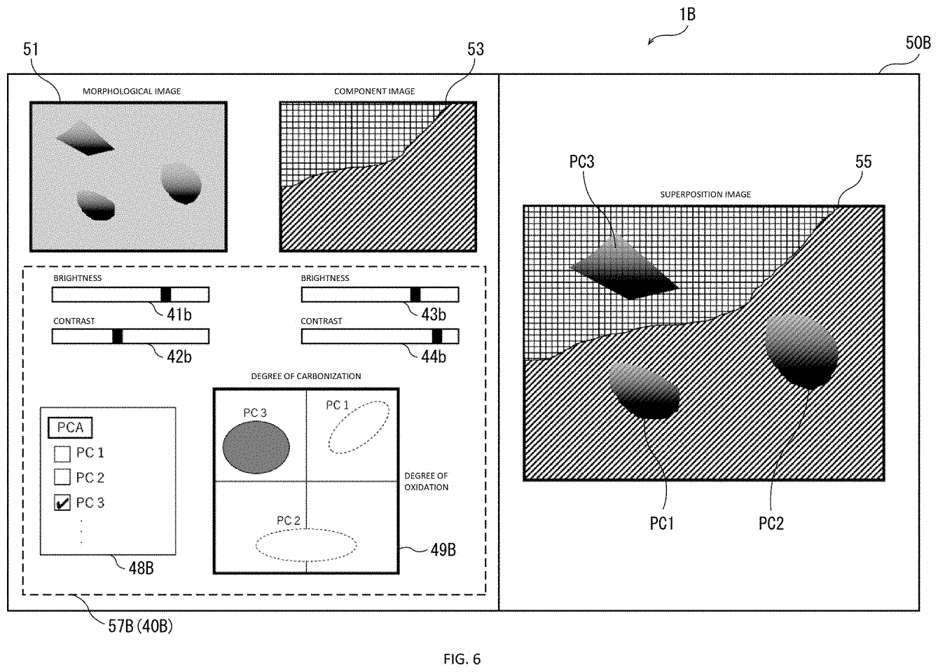

FIG. 6 is a chart illustrating a display unit 50B of a scanning electron microscope 1B according to the third embodiment of the present invention and illustrates an example of a display screen of the display unit 50B. The display unit 50B in the present embodiment is different from the display unit 50A in the second embodiment in that an image parameter display area 57B has a window 48B to select principal components PC1, PC2, and PC3 and a two dimensional map 49B displays degrees of oxidation and degrees of carbonization of the principal components PC1, PC2, and PC3.

In the present embodiment, the component calculation unit 34 of the component image generation unit 30 performs principal component analysis of the spectra of the characteristic X-rays obtained by the X-ray detector 32 for classification into each component to assign predetermined color information and thus generates image data of the component image (component image information).

Use of the window 48B then allows selecting a principal component that a user intends to focus on.

For example, as illustrated in FIG. 6, when a user selects the principal component “PC3” in the window 48B, a region of “PC3” on the two dimensional map 49B is displayed and an area corresponding to the “PC3” in the superposition image is also displayed with emphasis.

As just described, the present embodiment is configured to display, by specifying the principal component extracted from the principal component analysis by a user, two parameters (e.g., the degree of oxidation and the degree of carbonization) related to the principal component and also to change the brightness value of the superposition image in accordance with the two parameters related to the principal component, thereby obtaining an image highly visible for the user.

It should be noted that, although the present embodiment is configured to allow selection of a principal component that a user intends to focus on using the window 48B, the selection is not limited to such a configuration and a principal component that a user intends to focus on may be selected by, for example, directly touching any of the regions of the principal components PC1, PC2, and PC3 displayed on the two dimensional map 49B.

### Aspects

Those skilled in the art understand that the plurality of embodiments described above as exemplifications are specific examples of the following aspects.

First Aspect: A scanning electron microscope according to an aspect is a scanning electron microscope for observing a sample by irradiating the sample with an electron ray, the scanning electron microscope including:
a morphological calculation unit configured to calculate intensity data of at least one of secondary electrons and reflected electrons obtained from the sample to obtain morphological image information of the sample;

a component calculation unit configured to calculate spectrum data of X-ray energy obtained from the sample to obtain component image information of the sample; and

a display unit configured to display an image visualized by combining the morphological image information with the component image information, wherein

the morphological calculation unit is configured to change the morphological image information in accordance with one or more morphological image parameters input by a user, and

the component calculation unit is configured to change the component image information in accordance with one or more component image parameters input by a user.

The scanning electron microscope according to the first aspect allows the morphological image parameters and the component image parameters to be separately changed, and thus the image visualized by combining the morphological image information with the component image information is allowed to be most visible for a user.

Second Aspect: In the scanning electron microscope according to the first aspect,

the display unit is further configured to display at least one of a morphological image produced by visualizing the morphological image information and a component image produced by visualizing the component image information.

The scanning electron microscope according to the second aspect allows simultaneous observation of at least one of the morphological image and the component image, in addition to the image visualized by combining the morphological image information with the component image information.

Third Aspect: In the scanning electron microscope according to the first or second aspect,

the display unit is configured to display values of two parameters selected from a parameter group including the one or more morphological image parameters, the one or more component image parameters, and an arbitrary parameter related to any of the morphological or component image parameters on a two dimensional map, and

the morphological calculation unit and the component calculation unit are configured to change the morphological image information and the component image information, respectively, in accordance with a coordinate value specified by a user on the two dimensional map.

The scanning electron microscope according to the third aspect allows a simultaneous change in the two parameters by one operation on the two dimensional map.

Fourth Aspect: In the scanning electron microscope according to the third aspect,

the one or more morphological image parameters and the one or more component image parameters respectively include brightness and contrast.

The scanning electron microscope according to the fourth aspect allows the brightness and the contrast of the morphological image and the component image to be readily changed, and thus the image produced by superposing the morphological image and the component image is allowed to be most visible for a user.

Fifth Aspect: In the scanning electron microscope according to the third or fourth aspect,

the parameter related to the one or more component image parameters includes at least one of a degree of oxidation and a degree of carbonization.

The scanning electron microscope according to the fifth aspect allows changes in the parameters of the morphological image and the component image in accordance with the degree of oxidation and the degree of carbonization of a principal component, and thus the image produced by superposing the morphological image and the component image is allowed to be most visible for a user.

Sixth Aspect: A scanning electron microscope according to an aspect is a scanning electron microscope for observing a sample by irradiating the sample with an electron ray, the scanning electron microscope including:

a morphological calculation unit configured to calculate intensity data of at least one of secondary electrons and reflected electrons obtained from the sample to obtain morphological image information of the sample;

a component calculation unit configured to calculate spectrum data of X-ray energy obtained from the sample to obtain component image information of the sample; and

a display unit configured to display an image visualized by combining the morphological image information with the component image information, wherein

the display unit configured to display values of two arbitrary parameters related to a component of the sample as a point or region on a two dimensional map, and

the component calculation unit is configured to change the component image information in accordance with a position of the point or region on the two dimensional map specified by a user.

The scanning electron microscope according to the sixth aspect allows changes in the parameters of the component image in accordance with the values of two arbitrary parameters related to the component, and thus the image produced by superposing the morphological image and the component image is allowed to be most visible for a user.

Seventh Aspect: In the scanning electron microscope according to the sixth aspect,

the two parameters related to the component of the sample are a degree of oxidation and a degree of carbonization.

The scanning electron microscope according to the seventh aspect allows changes in the parameters of the component image in accordance with the degree of oxidation and the degree of carbonization of a principal component, and thus the image produced by superposing the morphological image and the component image is allowed to be most visible for a user.

1. A scanning electron microscope for observing a sample by irradiating the sample with an electron ray, the scanning electron microscope comprising:
a morphological calculation unit configured to calculate intensity data of at least one of secondary electrons and reflected electrons obtained from the sample to obtain morphological image information of the sample;
a component calculation unit configured to calculate spectrum data of X-ray energy obtained from the sample to obtain component image information of the sample; and
a display unit configured to display an image visualized by combining the morphological image information with the component image information, wherein
the morphological calculation unit is configured to change the morphological image information in accordance with one or more morphological image parameters input by a user, and
the component calculation unit is configured to change the component image information in accordance with one or more component image parameters input by a user.

2. The scanning electron microscope according to claim 1, wherein the display unit is further configured to display at least one of a morphological image produced by visualizing the morphological image information and a component image produced by visualizing the component image information.

3. The scanning electron microscope according to claim 1, wherein
the display unit is configured to display values of two parameters selected from a parameter group including the one or more morphological image parameters, the one or more component image parameters, and an arbitrary parameter related to any of the morphological or component image parameters on a two dimensional map, and
the morphological calculation unit and the component calculation unit are configured to change the morphological image information and the component image information, respectively, in accordance with a coordinate value specified by a user on the two dimensional map.

4. The scanning electron microscope according to claim 3, wherein the one or more morphological image parameters and the one or more component image parameters respectively include brightness and contrast.

5. The scanning electron microscope according to claim 3, wherein the parameter related to the one or more component image parameters includes at least one of a degree of oxidation and a degree of carbonization.

6. A scanning electron microscope for observing a sample by irradiating the sample with an electron ray, the scanning electron microscope comprising:
a morphological calculation unit configured to calculate intensity data of at least one of secondary electrons and reflected electrons obtained from the sample to obtain morphological image information of the sample;
a component calculation unit configured to calculate spectrum data of X-ray energy obtained from the sample to obtain component image information of the sample; and
a display unit configured to display an image visualized by combining the morphological image information with the component image information, wherein
the display unit configured to display values of two arbitrary parameters related to a component of the sample as a point or region on a two dimensional map, and
the component calculation unit is configured to change the component image information in accordance with a position of the point or region on the two dimensional map specified by a user.

7. The scanning electron microscope according to claim 6, wherein the two parameters related to the component of the sample are a degree of oxidation and a degree of carbonization.

8. The scanning electron microscope according to claim 4, wherein the parameter related to the one or more component image parameters includes at least one of a degree of oxidation and a degree of carbonization.

9. The scanning electron microscope according to claim 2, wherein
the display unit is configured to display values of two parameters selected from a parameter group including the one or more morphological image parameters, the one or more component image parameters, and an arbitrary parameter related to any of the morphological or component image parameters on a two dimensional map, and
the morphological calculation unit and the component calculation unit are configured to change the morphological image information and the component image information, respectively, in accordance with a coordinate value specified by a user on the two dimensional map.

10. The scanning electron microscope according to claim 9, wherein the one or more morphological image parameters and the one or more component image parameters respectively include brightness and contrast.

11. The scanning electron microscope according to claim 10, wherein the parameter related to the one or more component image parameters includes at least one of a degree of oxidation and a degree of carbonization.

12. The scanning electron microscope according to claim 9, wherein the parameter related to the one or more component image parameters includes at least one of a degree of oxidation and a degree of carbonization.
